(19) United States
(12) Patent Application Publication
(10) Pub. No.: US 2012/0018762 A1
(43) Pub. Date: Jan. 26, 2012

(54) SEMICONDUCTOR DEVICE

(76) Inventor: Osamu Abe, Tokyo (JP)

(21) Appl. No.: 13/260,750

(22) PCT Filed: Apr. 5, 2010
(86) PCT No.: PCT/JP2010/056490

§ 371 Date: Sep. 28, 2011

(30) Foreign Application Priority Data
Apr. 5, 2010 (JP) 2009-93500

(51) Int. Cl. H01L 33/60; H01L 31/0232

(52) U.S. Cl. 257/98; 257/432; 257/E33.072; 257/E31.127

(57) ABSTRACT

This disclosure provides a semiconductor device that can demonstrate an efficient heat releasing effect. The device includes a mount part 11 having a mount surface 6 on which a semiconductor device 3 is mounted, and a reflection part 12 having a reflection surface 7 on which light is reflected around the semiconductor device 3, and a heat releasing part 13 having a first heat releasing surface 8 for releasing heat. The mount part 11, the reflection part 12, and the heat releasing part 13 are integrally formed of metal. Therefore, heat generated in the semiconductor device 3 is promptly conducted to the heat releasing part 13 that is integrally formed with the mount part 11, thereby the heat is effectively released from the first heat releasing surface 8. In addition, heat accumulated in the reflection part 12 by light being irradiated to the reflection surface 7 is also promptly conducted to the heat releasing part 13 that is integrally formed with the reflection part 12, thereby the heat is effectively released from the first heat releasing surface 8.

### TECHNICAL FIELD

The present invention relates to a semiconductor device of optical functionality on which, for example, a light emitting element or a light receiving element is mounted.

### RELATED ART

Conventionally, semiconductor light emitting devices on which a light emitting element, such as an LED, is mounted have been widely used as semiconductor devices of optical functionality. Such a semiconductor light emitting device is necessary to have a reflection part which reflects light emitted from the light emitting element to uniformly and efficiently reflect the light to the outside, as well as to effectively release heat from a mount part of the element or the reflection part so that a stable optical characteristic in which an intensity distribution or an angle of radiation of the light does not vary with a temperature change can be acquired.

The following Patent Documents 1 and 2 disclose such a semiconductor device having the reflection part, for example.

### RELATED ART DOCUMENTS

### Patent Documents

Patent Document 1: JP3991624B2

Patent Document 2: JP4009208B2

### SUMMARY OF THE INVENTION

### Problems To Be Solved By the Invention

The semiconductor device disclosed in Patent Document 1 is provided with a thin plate (13) on which a LED chip (16) is mounted, and a metal substrate (15) joined to the thin plate (13). In this semiconductor device, the metal substrate (15) functions as a heat releasing part and a reflector part, and first and second metal thin plates (13b, 13c) which constitute the thin plate (13) function as an electrical connecting part (e.g., FIG. 1 and paragraphs 0019, 0020, 0023, and 0031 of the patent publication; the numerals in the parentheses are identical to the numerals used in the publication).

The semiconductor device disclosed in Patent Document 2 is provided with a base (2) on which a light emitting element (5) is mounted, a first frame (3) formed with a wiring conductor (3a), and a second frame (4) attached onto the first frame (3). In this semiconductor device, the base (2) functions as a heat releasing member and the second frame (4) functions as a reflection part. The wiring conductor (3a) provided to the first frame (3) functions as an electrical connecting part (e.g., FIG. 1 and paragraphs 0018 and 0019, and 0024 of the patent publication; the numerals in the parentheses are identical to the numerals used in the publication).

In the semiconductor device disclosed in Patent Document 1, the mount part (thin plate (13)) on which the light emitting element (5) is mounted and the electrical connecting part (first and second metal thin plates (13b, 13c)), and the reflection part and the heat releasing part (metal substrate (15)) are formed from separate parts.

Also in the semiconductor device disclosed in Patent Document 2, the mount part (base (2)) on which the light emitting element (5) is mounted and which also functions as a heat releasing part, and the member (first frame (3)) having the electrical connecting part (wiring conductor (3a)) and the reflection part (the second frame (4)) are formed from separate parts.

In Patent Documents 1 and 2, since the semiconductor device is comprised of a combination of a plurality of parts, a reduction of a thermal conductivity in joining portions of the parts.

That is, in the device of Patent Document 1, the thin plate (13) on which the light emitting element (5) is mounted and the metal substrate (15) which functions a reflection part are pasted together with an adhesive film (19) (paragraph 0031 (the fourth process) of the patent publication). Therefore, the intervention of the adhesive film (19) interrupts heat conduction and disturbs the heat releasing ability.

Moreover, in the device of Patent Document 2, the base (2) on which the light emitting element is mounted and the second frame (4) which functions a reflection part are joined together through the first frame (3) made of a ceramic or resin (for example, paragraph 0021 of the patent publication). Therefore, the intervention of the ceramic and resin interrupts heat conduction and disturbs the heat releasing ability.

Moreover, in the semiconductor device having the reflection part as described above, it is necessary to efficiently release the heat which is directly emitted from the light emitting element (5) and the LED chip (16), as well as to efficiently release the heat accumulated in the reflection part due to the light irradiated to the reflection part.

However, in Patent Documents 1 and 2, the semiconductor device has a problem that effective heat release is interrupted due to the disturbance of the thermal conduction by combining the plurality of parts. Thus, when the heat releasing effect is interrupted, there is a possibility that a variation may be caused in the light intensity, intensity distribution, radiation angle, etc., due to a temperature increase of the light emitting element (5) and the LED chip (16), thereby its optical characteristic may become unstable. Moreover, when the plurality of parts are combined, a strain is easy to be produced in the joining part due to a difference in the thermal expansion coefficient between the parts, and a reduction of the reliability due to a mechanical stress or the like may be concerned.

The present invention is made in view of such a situation, and the object of the invention is to provide a semiconductor device that can efficiently demonstrate a heat releasing effect.

### Means For Solving the Problem

In order to achieve the above object, the summary of the semiconductor device of the present invention is to include a mount part having a mount surface on which semiconductor device is mounted, a reflection part having a reflection surface on which light is reflected around the semiconductor device, and a heat releasing part having a heat releasing surface for releasing heat, and the mount part, the reflection part, and the heat releasing part are integrally formed of metal.

### Effect of the Invention

The semiconductor device of the present invention includes a mount part having a mount surface on which semiconductor device is mounted, a reflection part having a reflection surface on which light is reflected around the semiconductor device, and a heat releasing part having a heat releasing surface for releasing heat. The mount part, the reflection part, and the heat releasing part are integrally formed of metal.

For this reason, heat generated in the semiconductor device is promptly conducted to the heat releasing part that is integrally formed with the mount part, thereby the heat is effectively released from the heat releasing surface. In addition, heat accumulated in the reflection part by light being irradiated to the reflection surface is also promptly conducted to the heat releasing part that is integrally formed with the reflection part, thereby the heat is effectively released from the heat releasing surface. Thus, the performance reduction and degradation of the semiconductor device due to the heat can be prevented by promptly releasing the heat. For example, when the semiconductor device is a light emitting element, stable optical characteristics can be maintained because it prevents variations in an intensity, intensity distribution, angle of radiation, etc. of light. Moreover, a concern of a reduction of reliability due to a distortion caused in joints of the parts and a mechanical stress applied to the joints, like the conventional device which combined a plurality of parts can be eliminated.

In the semiconductor device, the heat releasing surface of heat releasing part that is integrally formed with the mount part and the reflection part may also serve as an attaching surface to an installation surface on which the semiconductor device is installed.

In this case, heat generated in the semiconductor device or heat accumulated in the reflection part is promptly conducted to the heat releasing part that is integrally formed with the mount part and the reflection part, thereby the heat is effectively released from the heat releasing surface to the installation surface. Moreover, only attaching the semiconductor device to the installation surface establishes a structure where the heat is effectively released from the heat releasing surface to the installation surface and, thus, it is not necessary to provide other structures for the heat release, thereby simplifying the structure.

In the semiconductor device, the heat releasing part that is integrally formed with the mount part and the reflection part may also serve as an electrical connecting part for electrically connecting with an exterior device when the semiconductor device is installed.

In this case, heat generated in the semiconductor device or heat accumulated in the reflection part is promptly conducted to the heat releasing part that is integrally formed with the mount part and the reflection part, and the heat is then effectively released from the heat releasing surface to the outside. Moreover, only electrically connecting the semiconductor device with the external device establishes the structure where heat is effectively released from the heat releasing surface to the installation surface and, thus, it is not necessary to additionally provide a structure for the heat release, thereby simplifying the structure.

In the semiconductor device, the mount part and the reflection part may be formed so that a surface ranging from the mount surface to the reflection surface forms the reflection surface having an upwardly spreading shape using the mount surface as its bottom. A surface opposite from the mount surface of the mount part may be arranged at the same level as the heat releasing surface of the heat releasing part to function as a second heat releasing surface.

In this case, heat generated in the semiconductor device is partially released from the mount surface of the mount part, and then, from the second heat releasing surface through the mount part, another part is released from the heat releasing surface through the reflection part and the heat releasing part. Thus, because the heat is released from both the heat releasing surface and the second heat releasing surface, a heat releasing efficiency is significantly improved.

Moreover, in this case, when the heat releasing surface and the second heat releasing surface also serve as the attaching surface to the installation surface on which the semiconductor device is installed, heat generated in the semiconductor device and heat accumulated in the reflection part are effectively released from the heat releasing surface and the second heat releasing surface to the installation surface. Therefore, only attaching the semiconductor device to the installation surface establishes the structure where the heat is effectively released from the heat releasing surface and the second heat releasing surface to the installation surface and, thus, it is not necessary to additionally provide a structure for the heat release, thereby simplifying the structure.

The semiconductor device may also include a second base electrically connected with the semiconductor device through a wiring conductor, other than the first base where the mount part, the reflection part, and the heat releasing part are integrally formed. In addition, a connecting part of the second base with of the wiring conductor may be arranged at a position higher than an upper end of the reflection surface formed in the upwardly spreading shape.

In this case, when electrically connecting the semiconductor device with the second base through the wiring conductor, it can effectively prevent a short circuit due to the wiring conductor contacting the upper end of the reflection surface.

### BRIEF DESCRIPTION OF THE DRAWINGS

FIG. 1 is views showing a semiconductor device according to a first embodiment of the present invention.

FIG. 2 is a view for illustrating a method of manufacturing the semiconductor device.

FIG. 3 is views showing a semiconductor device according to a second embodiment of the present invention.

FIG. 4 is a view showing a semiconductor device of a third embodiment of the present invention.

### BEST MODE FOR CARRYING OUT THE INVENTION

Below, the best mode for carrying out the present invention is described.

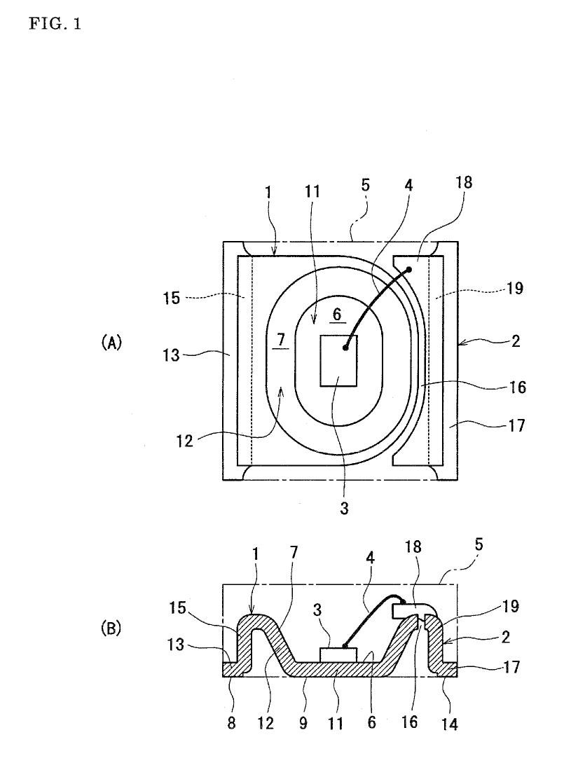

FIG. 1 is views showing a semiconductor device according to the present invention, where FIG. 1(A) is a plan view thereof and FIG. 1(B) is a cross-sectional view.

In this example, the semiconductor device includes a first base 1 on which a semiconductor device 3 is mounted, a second base 2 electrically connected with the semiconductor device 3 through a wiring conductor 4. An upper side of the first base 1, the second base 2, the semiconductor device 3, and the wiring conductor 4, which is a side where the semiconductor device 3 is mounted, is covered with a mold resin 5.

In this example, a light emitting element is used as the semiconductor device 3, and a transparent resin is used as the mold resin 5. The upper side covered with the mold resin 5 is used as a light emitting side from which the light is emitted. Note that, a light receiving element may be used as the semiconductor device 3, a transparent resin may be used as the mold resin 5, and the upper side covered with the mold resin 5 may be used as a light receiving side where the light is received.

The first base 1 includes a mount part 11 made of metal and having a mount surface 6 on which the semiconductor device 3 is mounted, a reflection part 12 having a reflection surface 7 on which light is reflected around the semiconductor device 3, and a heat releasing part 13 having a first heat releasing surface 8 for releasing heat. The first base 1 is constructed so that the mount part 11, the reflection part 12, and the heat releasing part 13 are integrally formed with the metal.

In this example, as for the first base 1, the first heat releasing surface 8 of the heat releasing part 13 integrated with the mount part 11 and the reflection part 12 is used as an attaching surface to a installation surface on which the semiconductor device is installed, and the heat releasing part 13 serves as an attaching part to the installation surface. That is, the heat releasing surface 8 of the heat releasing part 13 is located in a lower surface which is opposite to the light emitting side or the light receiving side which are covered with the mold resin 5, and this semiconductor device is installed in a state where the first heat releasing surface 8 faces to the installation surface. Moreover, the first heat releasing surface 8 directly contacts the installation surface in a state where the metal of the first heat releasing surface 8 is exposed without being covered with the mold resin 5 to release the heat as the heat is conducted from the heat releasing surface to the installation surface.

Moreover, in this example, the heat releasing part 13 which is integrally formed with the mount part 11 and the reflection part 12 serves as the electrical connecting part for electrically connecting the semiconductor device with the exterior device, when the semiconductor device is installed. That is, the first heat releasing surface 8 directly touches contacts, such as external terminals in the state where the metal of the first heat releasing surface 8 is exposed without being covered with the mold resin 5 as described above to electrically connect with the contacts.

Moreover, in the first base 1, the mount part 1 and the reflection part 12 are formed so that a surface ranging from the mount surface 6 to the reflection surface 7 is formed as the reflection surface 7 having an upwardly spreading shape using the mount surface 6 as its bottom. In this example, the mount surface 6 is formed in a track shape of an ellipse, and the reflection surface 7 is formed in a substantially earthenware mortar shape around the mount surface 6.

Moreover, in this example, the heat releasing part 13 is formed on one side of the ellipse shape of the mount part 1 and the reflection part 12. The heat releasing part 13 is formed by being bent in a lateral direction at a lower end of a vertical wall 15. The vertical wall 15 is provided along the long axis of the ellipse and is formed by being bent downwardly from an upper edge of the substantially earthenware mortar shaped reflection part 12.

In this example, an opposite surface of the mount surface 6 of the mount part 11 functions as a second heat releasing surface 9 so that the opposite surface is located at the same level as the first heat releasing surface 8 of the heat releasing part 13.

Whereas, the second base 2 is made of metal similar to the first base 1, and is formed separately from the first base 1 where the mount part 11, the reflection part 12, and the heat releasing part 13 are integrally formed. The second base 2 is electrically connected with the semiconductor device 3 through the wiring conductor 4.

The second base 2 is provided so that it separates from the first base 1 by a predetermined gap 16 therebetween, and it is formed along the long axis of the ellipse on the opposite side of the heat releasing part 13. The second base 2 is formed with a vertical wall 19 which is bent downwardly from an upper edge separated from the upper edge of the reflection part 12 by the gap 16 therebetween, and is formed with a installation part 17 which is bent laterally at a lower end of the vertical wall 19.

The installation part 17 of the second base 2 is formed symmetrical to the heat releasing part 13 of the first base 1 with respect to the long axis of the ellipse, and in this semiconductor device, a lower surface of the installation part 17 and a lower surface of the heat releasing part 13 serve as an attaching surface 14 to the installation surface on which the semiconductor device is installed. Moreover, the lower surface of the installation part 17 directly touches contacts, such as external terminals, to electrically connect with the contacts, and the installation part 17 also has a function as an electrical connecting part.

Moreover, in this example, a connecting part 18 connected with the wiring conductor 4 is provided to the second base 2, and the connecting part 18 of the second base 2 with the wiring conductor 4 is arranged at a position higher than the upper end of the reflection part 12 formed in the upwardly spreading shape. In this case, as described later, when the first base 1 and the second base 2 are simultaneously fabricated from a leadframe which is a single metal plate, since it is hard to avoid that the predetermined gap 16 is formed between the first base 1 and the second base 2, the connecting part 18 of the second base 2 with the wiring conductor 4 is arranged at the position higher than the upper end of the reflection part 12 to effectively prevent a short circuit due to the contact of the wiring conductor 4 and the second base 2.

In this example, the first base 1 is formed by press molding, such as deep drawing and bending, the single metal plate. The second base 2 is also formed by press molding, such as bending, the single metal plate similar to the first base 1.

In this example, as described above, the heat releasing part 13 of the first base 1 also serves as the electrical connecting part for electrically connecting with an exterior device, when the semiconductor device is installed, and serves as the attaching surface to the installation surface. Moreover, the installation part 17 which is the attaching part to the installation surface of the second base 2 serves as the electrical connecting part for electrically connecting with an exterior device.

That is, the first base 1 on which the semiconductor device 3 is mounted is a conductor, and the heat releasing part 13 which is the attaching part to the installation surface functions as a first electrode. The second base 2 connected with the semiconductor device 3 through the wiring conductor 4 is also a conductor, and the installation part 17 which is the attaching part to the installation surface functions as a second electrode. Thus, the configuration in which a portion that functions as the first electrode is provided to the first base 1 on which the semiconductor device 3 is mounted, and a portion that functions as the second electrode is provided to the second base 2 connected with the semiconductor device 3 through the wiring conductor 4, is effective in the semiconductor device where a single semiconductor device 3 is mounted to the mount part 11.

Thus, in the first base 1, since the heat releasing part 13 that is responsible for the heat releasing function has a plurality of functions, such as not only the heat releasing function but also the function as the attaching part to the installation surface and the function as the electrical connecting part with the exterior device, it is not necessary to additionally provide a functional part for every function. Therefore, it becomes simple as the whole device and a size reduction can also be achieved. Moreover, also in the second base 2, since the installation part 17 that is responsible for the attachment function to the installation surface has the function as the electrical connecting part for electrically connecting with the exterior device, it is not necessary to additionally provide a functional part for every function. Therefore, it becomes simple as the whole device and a size reduction can also be achieved.

Here, although the metallic material that constitutes the first base 1 is not particularly limited, an appropriate material may be adopted taking thermal conductivity, electrical conductivity, expansibility, corrosion resistance, reflective efficiency, etc. into consideration, and a surface treatment, such as plating, may also be performed suitably. As what fulfills each of the characteristics, for example, aluminum, silver, an iron-nickel alloy, etc. may also be used, but a material which gives silver plating to a copper material may be especially desirable. Moreover, as for the metallic material that constitutes the second base 2, similar materials to the first base 1 may also be selected.

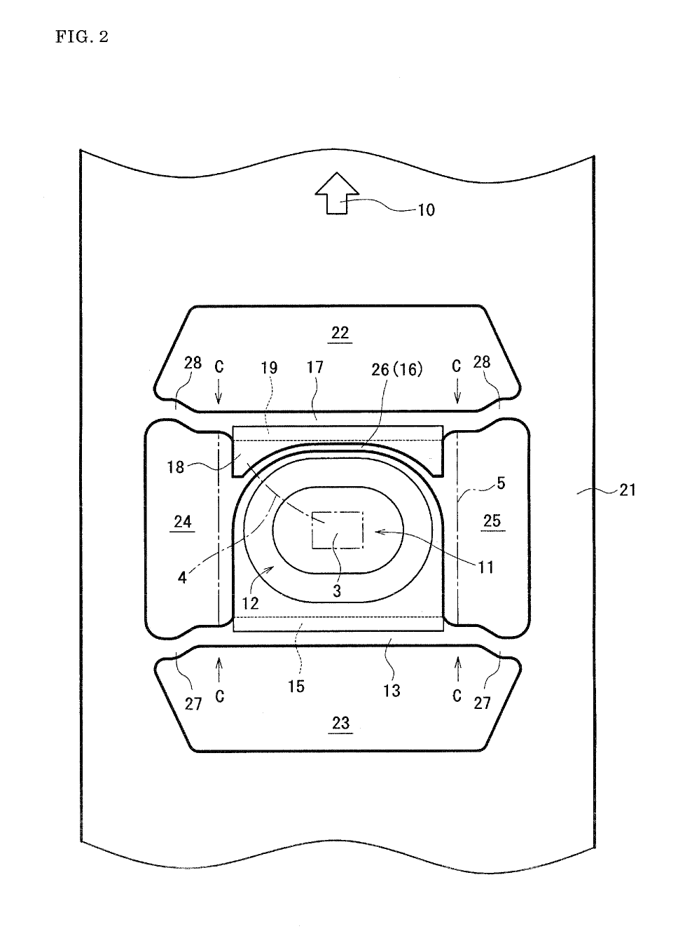

FIG. 2 is a view for illustrating a part of a process for manufacturing the semiconductor device.

The first base 1 and the second base 2 can be formed by press molding, such as plastically deforming, the single metal plate. That is, a leadframe 21 which is a belt-shaped metal plate is sequentially pierced by pressing to form a front opening 22, a rear opening 23, a left opening 24, and a right opening 25. The first base 1 and the second base 2 are fabricated in an area surrounded by the front opening 22, the rear opening 23, the left opening 24, and the right opening 25. Note that an arrow 10 indicates a moving direction of the leadframe 21 in this example.

The left opening 24 and the right opening 25 continue to each other through a curved slit 26 which serves as the gap 16 between the first base 1 and the second base 2 as described above. The second base 2 is fabricated in an area between the slit 26 and the front opening 22, and the first base 1 is fabricated in an area between the slit 26 and the rear opening 23.

Between the front opening 22, and the left opening 24 and the right opening 25, while having processed them, second coupling parts 28 for coupling the formed area of the second base 2 to the leadframe 21 are formed, respectively. Similarly, between the rear opening 23, and the left opening 24 and the right opening 25, while having processed them, first coupling parts 27 for coupling the formed area of the first base 1 to the leadframe 21 are formed, respectively.

In the leadframe 21 in the above states, the formed area of the second base 2 and the formed area of the first base 1 are given deep drawing and bending to fabricate the second base 2 and first base 1, respectively. That is, the first base 1 is formed by fabricating the mount part 11, the reflection part 12, the vertical wall 15, and the heat releasing part 13, etc., and the second base 2 is formed by fabricating the connecting part 18, the vertical wall 19, and the installation part 17, etc.

After the first base 1 and the second base 2 are fabricated, the semiconductor device 3 is mounted onto the mount part 11, and the connecting part 18 and the semiconductor device 3 are connected with each other through the wiring conductor 4. Next, the side on which the semiconductor device 3 is mounted is covered with the mold resin 5. After that, the first coupling part 27 and the second coupling part 28 are cut at cutting parts C to obtain the semiconductor device of this embodiment.

Note that, as described above, although the first base 1 and the second base 2 may also be simultaneously fabricated from the leadframe 21 of one sheet, they may be fabricated separately to make them one set of their combination to constitute the semiconductor device of the present invention.

As described above, the semiconductor device of this embodiment includes the mount part 11 having the mount surface 6 on which the semiconductor device 3 is mounted, the reflection part 12 having the reflection surface 7 on which light is reflected around the semiconductor device 3, and the heat releasing part 13 having the first heat releasing surface 8 for releasing heat. The mount part 11, the reflection part 12, and the heat releasing part 13 are integrally formed of metal.

For this reason, heat generated in the semiconductor device 3 is promptly conducted to the heat releasing part 13 which is integrally formed with the mount part 11, and the heat is effectively released from the first heat releasing surface 8. Moreover, heat accumulated in the reflection part 12 by light being irradiated to the reflection surface 7 is also promptly conducted to the heat releasing part 13 which is integrally formed with the reflection part 12, and the heat is effectively released from the first heat releasing surface 8. Thus, by performing the prompt heat release, a performance reduction or degradation of the semiconductor device 3 due to the heat can be prevented. For example, when the semiconductor device 3 is a light emitting element, stable optical characteristics can be maintained by preventing variations in the intensity, the intensity distribution, the angle of radiation, etc. of light. Moreover, a concern of a reduction in the reliability due to the joining portions of the parts being subjected to a distortion and a mechanical stress like the conventional device which combined a plurality of parts can be eliminated.

In the above embodiment, when the first heat releasing surface 8 of the heat releasing part 13 which is integrally formed with the mount part 11 and the reflection part 12 also serves as the attaching surface to the installation surface on which the semiconductor device is installed, heat generated in the semiconductor device 3 or heat accumulated in the reflection part 12 is promptly conducted to the heat releasing part 13 which is integrally formed with the mount part 11 and the reflection part 12, and the heat is effectively released from the first heat releasing surface 8 to the installation surface. Moreover, attaching the semiconductor device to the installation surface establishes the structure where heat is effectively released from the first heat releasing surface 8 to the installation surface and, thus, it is not necessary to provide an additional structure for the heat release, thereby simplifying the structure.

In the above embodiment, when the heat releasing part 13 which is integrally formed with the mount part 11 and the reflection part 12 also serves as the electrical connecting part for electrically connecting with the exterior device upon installing the semiconductor device, heat generated in the semiconductor device 3 or heat accumulated in the reflection part 12 is promptly conducted to the heat releasing part 13 which is integrally formed with the mount part 11 and the reflection part 12, and the heat is effectively released from the first heat releasing surface 8 to the outside. Moreover, electrically connecting the semiconductor device with the external device establishes the structure where heat is effectively released from the first heat releasing surface 8 to the installation surface and, thus, it is not necessary to provide an additional structure for the heat release, thereby simplifying the structure.

In the above embodiment, when the mount part 11 and the reflection part 12 are formed so that the surface ranging from the mount surface 6 to the reflection surface 7 is formed with the reflection surface 7 having the upwardly spreading shape using the mount surface 6 as its bottom, and the surface opposite from the mount surface 6 of the mount part 11 is constructed to be the same level with the first heat releasing surface 8 of the heat releasing part 13 to function as the second heat releasing surface 9, heat generated in the semiconductor device 3 is partially released from the mount surface 6 of the mount part 11, and then, from the second heat releasing surface 9 through the mount part 11, and another part is released from the first heat releasing surface 8 through the reflection part 12 and the heat releasing part 13. Thus, since the heat is released from both the first heat releasing surface 8 and the second heat releasing surface 9, a heat releasing efficiency is significantly improved.

Moreover, in this case, when the first heat releasing surface 8 and the second heat releasing surface 9 serve as the attaching surface to the installation surface on which the semiconductor device is installed, heat generated in the semiconductor device 3 and heat accumulated in the reflection part 12 are effectively released to the installation surface from the first heat releasing surface 8 and the second heat releasing surface 9. Thereby, attaching the semiconductor device to the installation surface establishes the structure where the heat is effectively released from the first heat releasing surface 8 and the second heat releasing surface 9 to the installation surface, and it is not necessary to provide an additional structure for the heat release, thereby simplifying the structure.

In the above embodiment, the device includes the second base 2 electrically connected with the semiconductor device 3 through the wiring conductor 4, separately from the first base 1 where the mount part 11, the reflection part 12, and the heat releasing part 13 are integrally formed. When the connecting part 18 of the second base 2 with the wiring conductor 4 is arranged at a position higher than the upper end of the reflection surface 7 formed in the upwardly spreading shape, upon electrically connecting the semiconductor device 3 with the second base 2 through the wiring conductor 4, it can effectively prevent the short circuit due to the wiring conductor 4 contacting the upper end of the reflection surface 7.

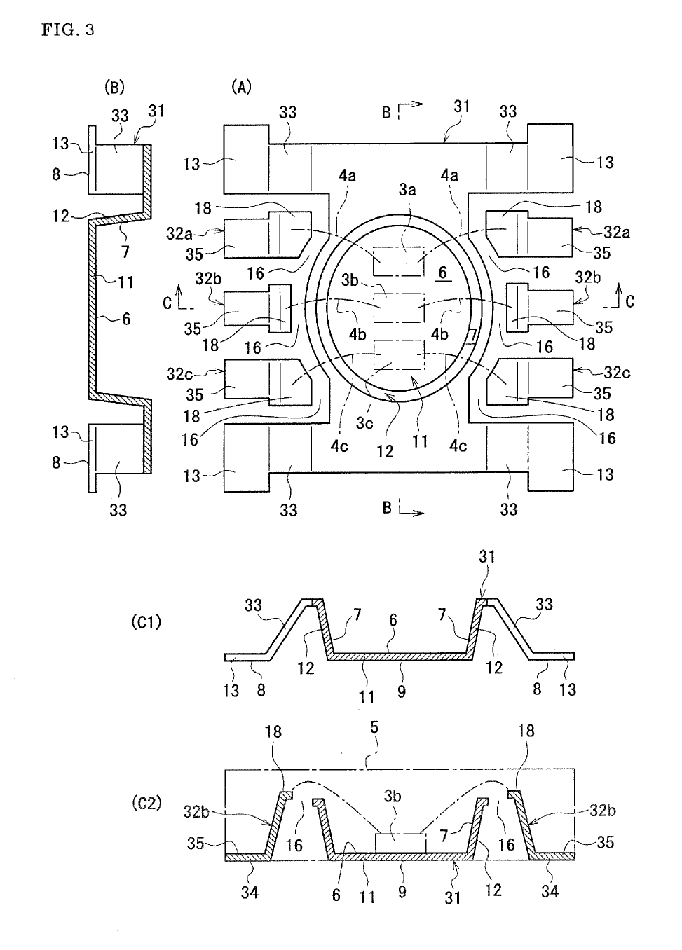

FIG. 3 is views showing a semiconductor device according to a second embodiment of the present invention.

FIG. 3(A) is a plan view of the semiconductor device comprised of a first base 31, and second bases 32a, 32b and 32c. FIG. 3(B) is a cross-sectional view of the first base 31 taken along a line B-B. FIG. 3(C1) is a cross-sectional view of the first base 31 taken along a line C-C, and FIG. 3(C2) is an end elevational view of the semiconductor device taken along a line C-C.

This example shows a structure where three semiconductor devices 3a, 3b, and 3c are mounted onto a mount part 11. For example, light emitting elements of three colors of RGB may be mounted.

The first base 31 is constructed by including the mount part 11 having a mount surface 6 of an ellipse shape, a reflection part 12 having a reflection surface 7 formed in an upwardly spreading shape around the mount surface 6, and heat releasing parts 13 formed in lower end parts of curved parts 33 which are bent downwardly from the upper edges of the reflection part 12 at four corners.

Whereas, a pair of the second bases 32a, a pair of the second bases 32b, and a pair of the second bases 32c are provided to the respective three semiconductor devices 3a, 3b, and 3c. Thus, the first semiconductor device 3a is electrically connected with the pair of second bases 32a through the respective wiring conductors 4a, and the pair of second bases 32a is responsible for a function as a first electrode and a second electrode of the semiconductor device 3a. Similarly, the second semiconductor device 3b is electrically connected with the pair of second bases 32b through the respective wiring conductors 4b, and the pair of second bases 32b is responsible for a function as a first electrode and a second electrode of the semiconductor device 3b. Furthermore, similarly, the third semiconductor device 3c is electrically connected with the pair of second bases 32c through the respective wiring conductors 4c, and the pair of second bases 32c is responsible for a function as a first electrode and a second electrode of the semiconductor device 3c.

Therefore, unlike the above first embodiment, this embodiment has a structure where the first base 31 does not have a portion which functions, as an electrical connecting part.

In this embodiment, lower surfaces of the four heat releasing parts 13 of the first base 31 are attaching surfaces to the installation surface and function as first heat releasing surfaces 8. Therefore, the four heat releasing parts 13 also function as attaching parts to the installation surface.

Whereas, the second bases 32a, 32b, and 32c are formed separately from the first base 31 where the mount part 11, the reflection part 12, and the heat releasing part 13 are integrally formed, and, as described above, they are electrically connected with the respective semiconductor devices 3a, 3b, and 3c through the respective wiring conductors 4a, 4b, and 4c.

The second bases 32a, 32b, and 32c are formed with downward curved parts from upper edges which oppose to upper edges of the reflection part 12 so as to be separated by predetermined gaps 16, and formed with electrical connecting parts 35 which are formed by bending laterally from lower ends of the curved parts and has the electrically connecting surfaces 34. Each of the second bases 32a, 32b, and 32c is provided with a connecting part 18 which is connected with the respective wiring conductors 4a, 4b, and 4c. The connecting parts 18 of the second bases 32a, 32b, and 32c with the wiring conductors 4a, 4b, and 4c are arranged at positions higher than the upper end of the reflection part 12 formed in the upwardly spreading shape.

Also in this embodiment, the first base 31 is formed by press molding, such as deep drawing and bending, a single metal plate. Each of the above second bases 32a, 32b and 32c is formed similarly by press molding, such as bending, a single metal plate. As described in the first embodiment, the first base 31, and the second bases 32a, 32b and 32c may be fabricated simultaneously from the leadframe 21 of one sheet, or may be fabricated separately and combine them into one set to construct the semiconductor device of the present invention.

Other than that, this embodiment is similar to the first embodiment and, thus, the same numerals are given to similar parts. Also in this example, similar operations and effects to those of the first embodiment can be attained.

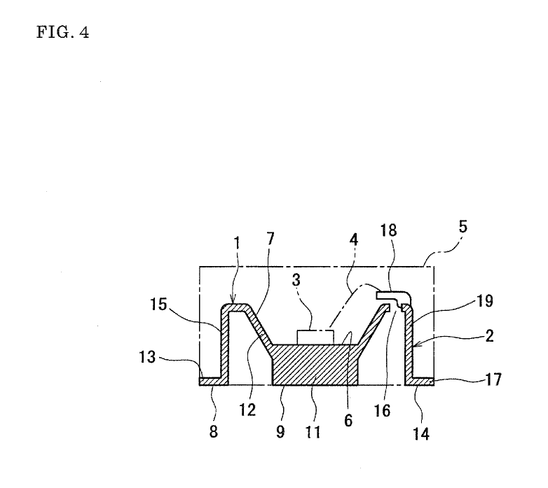

FIG. 4 is a view showing a semiconductor device according to a third embodiment of the present invention.

This example is configured such that a thickness of a mount part 11 of a first base 1 is set thicker than other parts, and according to this, a first heat releasing surface 8 and an attaching surface 14 of the second base 2 are arranged at the same level as a second heat releasing surface 9 which is a lower surface of the mount part 11 having a large thickness. In this example, since the mount part 11 on which the semiconductor device 3 is mounted is thickened, an efficiency of heat release from the second heat releasing surface 9 can be improved.

Also in this embodiment, the first base 1 can be formed by press molding, such as flatting, deep drawing and bending, a single metal plate. The first based 1 may be formed such that a thick plate is originally prepared in order to secure the thickness of the mount part 11, and other parts are extended thinly by flatting, and the think parts are further applied with deep drawing and bending. Also in this example, as described in the first embodiment, the first base 1 and the second base 2 may also be fabricated simultaneously from the leadframe 21 of one sheet, or may be fabricated separately and combined as one set to construct the semiconductor device of the present invention.

Other than that, this embodiment is similar to the first embodiment and, thus, the same numerals are given to similar parts. Also in this example, this embodiment can obtain similar operations and effects as the first embodiment.

Note that, although each of the above embodiments show that the surfaces which contact the installation surface (the first heat releasing surface 8, the attaching surface 14, the second heat releasing surface 9, etc.) are formed in the planar shapes, these surfaces may also be surfaces where convex portions, concave portions, etc. are formed, other than the planar shape. In these cases, it is preferable to attach to the installation surface through adhesives or the like having heat conductivity and electrical conductivity in a state where heat conductivity and electrical conductivity are secured.

### DESCRIPTION OF REFERENCE NUMERALS

1: First Base
2: Second Base
3: Semiconductor Device
3a: Semiconductor Device
3b: Semiconductor Device
3c: Semiconductor Device
4a: Wiring Conductor
4b: Wiring Conductor
4c: Wiring Conductor
4: Wiring Conductor
5: Mold Resin
6: Mount Surface
7: Reflection Surface
8: First Heat Releasing Surface
9: Second Heat Releasing Surface
10: Arrow
11: Mount Part
12: Reflection Part
13: Heat Releasing Part
14: Attaching Surface
15: Vertical Wall
16: Gap
17: Mounting Part
18: Connecting Part
19: Vertical Wall
21: Leadframe
22: Front Opening
23: Rear Opening
24: Left Opening
25: Right Opening
26: Slit
27: First Coupling Part
28: Second Coupling Part
31: First Base
32a: Second Base
32b: Second Base
32c: Second Base
33: Curved Part
34: Electrically Connection Surface
35: Electrically Connecting Part

1. A semiconductor device, comprising a mount part having a mount surface on which semiconductor device is mounted; a reflection part having a reflection surface on which light is reflected around the semiconductor device; and a heat releasing part having a heat releasing surface for releasing heat,
wherein the mount part, the reflection part, and the heat releasing part are integrally formed of metal.

2. The semiconductor device of claim 1, wherein the heat releasing surface of heat releasing part that is integrally formed with the mount part and the reflection part also serves as an attaching surface to an installation surface on which the semiconductor device is installed.

3. The semiconductor device of claim 1, wherein the heat releasing part that is integrally formed with the mount part and the reflection part also serves as an electrical connecting part for electrically connecting with an exterior device when the semiconductor device is installed.

4. The semiconductor device of claim 1, wherein the mount part and the reflection part are formed so that a surface ranging from the mount surface to the reflection surface forms the reflection surface having an upwardly spreading shape using the mount surface as its bottom, and
wherein a surface opposite from the mount surface of the mount part is arranged at the same level as the heat releasing surface of the heat releasing part to function as a second heat releasing surface.

5. The semiconductor device of claim 1, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

6. The semiconductor device according to claim 2, wherein the heat releasing part that is integrally formed with the mount part and the reflection part also serves as an electrical connecting part for electrically connecting with an exterior device when the semiconductor device is installed.

7. The semiconductor device according to claim 2, wherein the mount part and the reflection part are formed so that a surface ranging from the mount surface to the reflection surface forms the reflection surface having an upwardly spreading shape using the mount surface as its bottom, and
wherein a surface opposite from the mount surface of the mount part is arranged at the same level as the heat releasing surface of the heat releasing part to function as a second heat releasing surface.

8. The semiconductor device according to claim 3, wherein the mount part and the reflection part are formed so that a surface ranging from the mount surface to the reflection surface forms the reflection surface having an upwardly spreading shape using the mount surface as its bottom, and
wherein a surface opposite from the mount surface of the mount part is arranged at the same level as the heat releasing surface of the heat releasing part to function as a second heat releasing surface.

9. The semiconductor device according to claim 6, wherein the mount part and the reflection part are formed so that a surface ranging from the mount surface to the reflection surface forms the reflection surface having an upwardly spreading shape using the mount surface as its bottom, and
wherein a surface opposite from the mount surface of the mount part is arranged at the same level as the heat releasing surface of the heat releasing part to function as a second heat releasing surface.

10. The semiconductor device according to claim 2, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

11. The semiconductor device according to claim 3, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

12. The semiconductor device according to claim 4, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

13. The semiconductor device according to claim 6, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

14. The semiconductor device according to claim 7, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

15. The semiconductor device according to claim 8, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.

16. The semiconductor device according to claim 9, comprising a second base electrically connected with the semiconductor device through a wiring conductor, other than the first base where the mount part, the reflection part, and the heat releasing part are integrally formed,
wherein a connecting part of the second base with of the wiring conductor is arranged at a position higher than an upper end of the reflection surface formed in the upwardly spreading shape.
